(19) United States
(12) Patent Application Publication
(10) Pub. No.: US 2018/0034316 A1
(43) Pub. Date: Feb. 1, 2018

(54) DEVICE FOR COMMANDING/CONTROLLING A SOURCE CHANGEOVER SWITCH

(71) Applicant: Schneider Electric Industries SAS, Rueil Malmaison (FR)

(72) Inventor: Alain RET, Montchaboud (FR)

(73) Assignee: Schneider Electric Industries SAS, Rueil Malmaison (FR)

(21) Appl. No.: 15/660,222

(22) Filed: Jul. 26, 2017

(30) Foreign Application Priority Data
Jul. 27, 2016 (FR) 16 57195

(51) Int. Cl. H02J 9/06; G01R 31/40; G01R 31/36

(52) U.S. Cl. CPC H02J 9/062; H02J 9/061; G01R 31/362; G01R 31/40

(57) ABSTRACT

A device is intended to monitor/control switches that are arranged to connect at least two electrical power sources to an electrical load depending on the availability of the sources. The device includes monitoring/control circuits; a supply bus; first and second voltage converters arranged to respectively convert a first voltage of the first power source and a second voltage of the second power source to an intermediate voltage for supplying the supply bus; and a third voltage converter arranged to convert the voltage of the supply bus to a useful voltage for supplying the monitoring/control circuits. A source changeover switch can include such a device and to a method can supply the monitoring/control device with power.

### TECHNICAL FIELD

The invention relates to a device intended to monitor/control at least one first and one second switch that are arranged to connect at least one first and one second electric power source, respectively, to an electrical load depending on the availability of said sources.

The invention also relates to a source changeover switch intended to connect a first and a second electric power source, respectively, to an electrical load depending on the availability of said sources.

The invention also relates to a method for supplying with power a device intended to monitor/control a source changeover switch.

### PRIOR ART

The availability of electric power is critical, inter alia for hospitals, for production industries unable to cope with untimely outages, or for installations that operate using large-scale computer facilities. Specifically, a disruption to the supply of electric power may cause significant damage: loss of production, loss of data, and, worse, loss of human life.

In order to avoid such consequences, a device that is generally called a source changeover switch is used: as soon as the main power source is no longer available, the source changeover switch automatically switches the source of electric power to a second available power source. This second source is generally a generating set, but may be a different electrical line or an output of a redundant transformer of the electrical installation. Moreover, it is becoming increasingly common to have a plurality of other power sources in order to mitigate any failure of the second source, for example a failure of the generating set to start or maintenance operations on the electrical line.

The second source provides power while the main source is unavailable. When the latter becomes available again, as a general rule, the source changeover switch disconnects the second source in order to automatically reconnect the user to the main source. Depending on the need of the user, there may be other ways of transitioning to a return to a normal situation.

As operational safety and the security of goods and/or individuals are a factor, the operation of the source changeover switch must be reliable and without malfunction: for example, it is not permitted to simultaneously connect two or more unsynchronized sources in order to prevent unacceptable overcurrents and voltage variations. To this end, for example in the simplest changeover switches having only two sources, the control of one of the switches is linked in series with a state sensor of the other switch, and vice versa, in order to ensure electrical self-locking of the switches. However, as soon as the installation has more than two sources, the wiring complexity becomes greater, with risks of incorrect wiring when installing the source changeover switch.

This complexity increases even further when the power of the electrical installation exceeds several hundred amperes: the switches used may be power circuit breakers providing the additional function of protecting against short circuits. These power circuit breakers have a more complex operation than simple contactors, in particular actuating them requires a step of rearming between opening and closure, and they may be connected or disconnected for maintenance operations. There is therefore a greater number of auxiliaries indicating their state than in the case of a simple contactor.

Moreover, electrical isolation between the various sources and their auxiliaries must be guaranteed in order to prevent undesired looping between the circuit of the main source and the circuit of the second source, which may result in a serious short circuit between the sources.

In addition, as electrical installations have to be adapted in line with the development of activities, and as users are increasingly demanding power to be available, it is necessary to be able to easily modify a source changeover switch without posing a risk to goods and individuals.

Finally, in the event of a power supply failure, it becomes vital to be able to diagnose the origin of the fault in order to rectify it as quickly as possible.

Document FR 3 026 245 is known and describes an interconnecting device intended to secure and facilitate connection in a source changeover switch. This device includes prewiring that facilitates the interconnection of the switches and of the monitoring/control housing of the source changeover switch. Although it offers a solution to the problem of simplifying the wiring and of reducing the risk of wiring errors, the interconnecting device does not allow easy integration of a third power source since, in this case, it would be necessary to create new wire harnesses.

Document U.S. Pat. No. 7,259,481 is known and describes a source changeover switch capable of adapting to a large range of variation in the voltage delivered by the second source. It is suitable for an electrical network having only two sources, and does not have galvanic separation between the two sources. The failure of a diode in the rectifier stage may create an inadvertent link between the circuit of the main source and the circuit of the second source, leading to a short circuit between the two sources. Furthermore, the invention is dedicated to a low-power installation: the relay used to switch the sources is not suitable for a high-power industrial installation using power switches having opening and closing modes in several steps. Finally, it does not allow easy integration of a third source, as the relay used has only two possible states.

### SUMMARY OF THE INVENTION

In order to rectify the abovementioned drawbacks of the prior art, the invention provides a device intended to monitor/control at least one first and one second switch that are arranged to connect at least one first and one second electric power source, respectively, to an electrical load depending on the availability of said sources, said device including:
a drive circuit,
monitoring/control circuits,
a supply bus,
a first voltage converter having an input linked to the first power source and an output connected to the supply bus, and arranged to convert a first voltage of the first power source to an intermediate voltage for supplying the supply bus,
a second voltage converter having an input linked to the second power source and an output connected to the supply bus, and arranged to convert a second voltage of the second power source to an intermediate voltage for supplying the supply bus,
a third voltage converter arranged to convert the intermediate voltage of the supply bus to a useful voltage for supplying the monitoring/control circuits.

The monitoring/control circuits preferably include:
a circuit for controlling the activation of the switches and/or
a circuit for monitoring the state of the switches and/or
a circuit for determining the availability of the sources.

The first and second converting means preferably include galvanic isolation between the first electric power source and the supply bus and between the second electric power source and the supply bus, respectively.

The first voltage converter preferably performs the conversion of the first voltage of the first power source to an intermediate voltage when the first voltage is higher than a first threshold. Identically, the second voltage converter performs the conversion of the second voltage of the second power source to an intermediate voltage when the second voltage is higher than a second threshold.

The intermediate voltage is advantageously a DC voltage.

The useful voltage is preferably substantially equal to the nominal operating voltage of the monitoring/control circuits.

A backup power supply device is advantageously connected to the supply bus to deliver the intermediate voltage to said supply bus when the first and the second power source are unavailable.

The backup power supply device advantageously includes a power storage means arranged to be charged to a storage voltage when the first and/or second power source are/is available.

According to one preferred embodiment, the intermediate voltage is substantially equal to the storage voltage of the power storage means of the backup device.

The drive circuit is preferably connected to the supply bus for its power supply.

Another subject of the invention is a source changeover switch intended to connect a first or a second electric power source, respectively, to an electrical load depending on the availability of said sources, said source changeover switch including:
at least one first and one second switch,
at least two control auxiliaries, each auxiliary being intended to control one switch, respectively,
one or more state sensors, each state sensor interacting with one switch, respectively, to detect the state of said switch, and
a monitoring/control device having one or more of the features described previously.

Preferably, the input of the first converting means is connected between the first source and the first switch, and the input of the second converting means is connected between the second source and the second switch.

The invention also relates to a method for supplying with power a device intended to monitor/control a source changeover switch having one or more of the features described previously, said method comprising the following steps:
converting the first voltage of the first power source to an intermediate voltage for supplying the supply bus by means of a first voltage converter,
converting the second voltage of the second power source to an intermediate voltage for supplying the supply bus by means of a second voltage converter,
converting the voltage of the supply bus to a useful voltage by means of a third voltage converter.

The method furthermore includes the following steps if a backup power supply device is present:
providing, by means of the backup power supply device, the intermediate voltage to the supply bus when the two means for converting the first voltage or the second voltage are not operational, otherwise,
recharging the storage means of the backup power supply device when the intermediate voltage is provided by at least one of the means for converting the first voltage or the second voltage.

All of the auxiliaries of the switches are thus supplied with a single useful voltage that is galvanically isolated and independent of the various power sources, and that has a stable and controlled amplitude. This layout makes it possible to simplify the wiring diagram of the auxiliaries and, as a result, to minimize the risks of wiring errors, while enabling easy expansion to additional power sources.

### BRIEF DESCRIPTION OF THE DRAWINGS

Other advantages and features will become more clearly apparent in the following description of particular embodiments of the invention, which are given by way of non-limiting examples and shown in the appended drawings in which:

FIG. 1 is a schematic representation of an electrical installation having a source changeover switch;

FIG. 2 is a schematic representation of a source changeover switch device used in the prior art;

FIG. 3 is a schematic representation of a source changeover switch device used with a monitoring/control device of the invention, in one preferred embodiment;

FIG. 4 is a flow chart illustrating a method for supplying with power the device for monitoring/controlling a source changeover switch.

### DETAILED DESCRIPTION OF PREFERRED EMBODIMENTS

In the description, the term ‘a source is available’ will be used to qualify a source with the capacity to deliver electric power. A source may deliver electric power in polyphase form, generally three-phase form in this case, or indeed in single-phase or DC form.

The term ‘switch’ will preferably be used to refer to an electrical circuit breaker, but may also refer to a contactor, one of the tracks of a dual contactor, a relay or indeed a semiconductor static electronic switch.

The term ‘upstream connection’ will be used to refer to a link to a power source, and the term ‘downstream connection’ will be used to refer to a link to a power receiver.

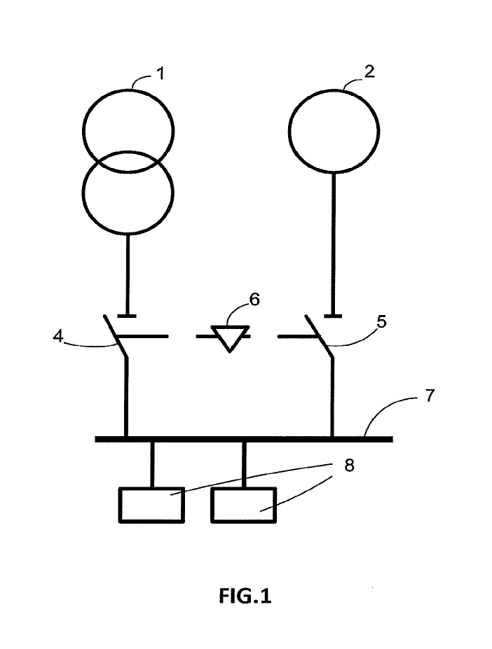

FIG. 1 is a conventional schematic representation of an electrical installation having a source changeover switch. A main source 1 provides electric power to one or more loads 8. A load 8 may be one device or a set of a plurality of devices the operation of which must not be interrupted, an industrial zone containing devices that must be supplied with power continuously, or a building of which the power supply is a vital aspect. A switch 4, connected upstream to the source 1 and downstream to a busbar 7, establishes the link between the source 1 and the busbar 7. The load 8 is connected to the busbar 7. The switch 4 may be a contactor, a relay or a circuit breaker.

In case of unavailability of the main source 1, for example following a wire breakage or a short circuit upstream of the installation, a second electric power source 2 is used to continue to supply the load 8 with power. This second source could be a local generator, such as a generating set. A switch 5, connected upstream to the second source 2 and downstream to the busbar 7, establishes the link between the second source 2 and the busbar 7.

It may be the case that the first source 1 and the second source 2 are available simultaneously. These two sources are not generally synchronized, and therefore, as they are not in phase with one another, it is imperative that they are not connected simultaneously to the busbar 7. One of the roles of the source changeover switch is to prevent this situation. To this end, an interlocking device 6 prevents the closure of one switch if the other switch is already closed. In contrast, the two switches may be simultaneously open, thus separating the busbar from each power source, for example in order to perform maintenance operations on the load.

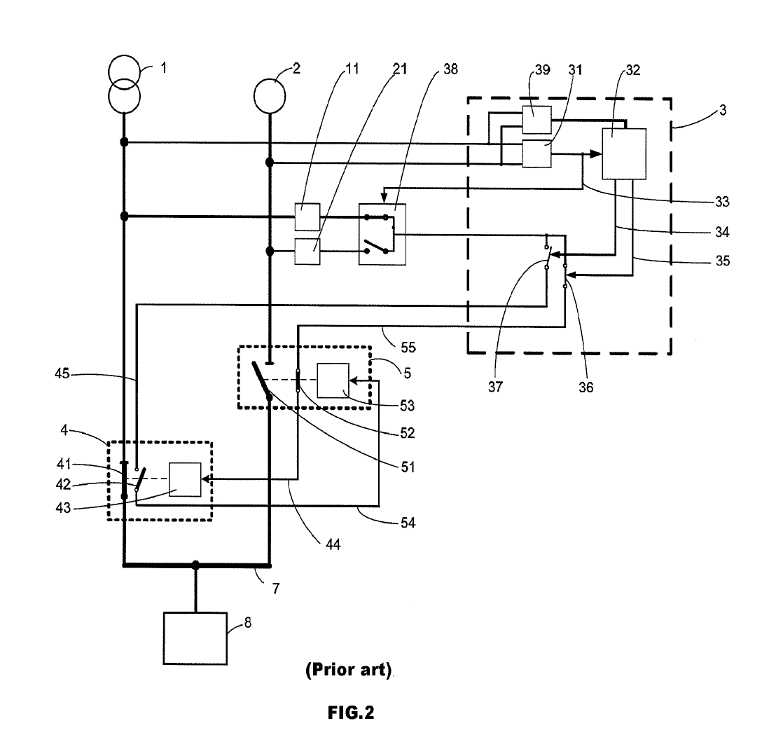

FIG. 2 is a schematic representation of a source changeover switch device as described in the prior art. A device 3 is intended to monitor/control the switches 4 and 5. The device 3 is supplied with power from power sources 1 and 2 by means of a power supply 39. This low-power power supply is linked to the power sources 1 and 2 and draws power from each of the sources for example through semiconductor rectifiers followed by voltage regulation, not shown in FIG. 2. A circuit 31 provides information relating to the available source(s) to a drive circuit 32 and to an auxiliary source changeover switch 38 by means of a link 33. Said auxiliary source changeover switch is connected upstream to the sources 1 and 2 and downstream to the contacts 36 and 37. Its function is to select the available power source in order to draw the power necessary to activate the switches 4 and 5, without creating an electrical link between the sources 1 and 2. An overcurrent protection device 11, such as a circuit breaker, protects the electrical link between the source 1 and the source changeover switch 38 from any overcurrent linked to a short circuit in the source changeover switch 38 or downstream thereof. Likewise, an overcurrent protection device 21 protects the electrical link between the source 2 and the source changeover switch 38 from any overcurrent linked to a short circuit in the source changeover switch 38 or downstream thereof.

A device such as the power supply 39 cannot be used to control the activation of the switches when the power demanded is too high, for example when the switches 4 and 5 are high-power circuit breakers.

The function of the drive circuit 32 is to control the contacts 36 and 37 depending on the information regarding the availability of the sources 1 and 2 that is delivered by the circuit 31.

The switch 4 is composed of a set of contacts 41 in order to establish the link between the source 1 and the busbar 7 when the contacts 41 are closed and to open said link when the contacts 41 are opened. A control auxiliary 43 controls the closure and the opening of the contacts 41 by converting a control received via the link 44 into an action to open and close the contacts 41. At least one state sensor 42 gives information regarding the open or closed state of the contact 41. This state sensor is generally an electrical contact called an ‘auxiliary contact’. It is linked mechanically to the contacts 41, and does not have any electrical link to the contacts 41 or to the control auxiliary 43. The electrical contact of the state sensor is preferably closed when the contacts 41 are open, and open when the contacts 41 are closed, as shown in FIG. 2.

Likewise, the switch 5 is composed of a set of contacts 51 in order to establish the link between the secondary source 2 and the busbar 7 when the contacts 51 are closed and to open said link when the contacts 51 are opened. A control auxiliary 53 controls the closure and the opening of the contacts 51 by converting a control received via the link 54 into an action to open and close the contacts 51. At least one state sensor 52 gives information regarding the open or closed state of the contact 51. As for the sensor 42, this state sensor is an electrical contact called an ‘auxiliary contact’. It is linked mechanically to the contacts 51, and does not have any electrical link to the contacts 51 or to the control auxiliary 53. The electrical contact of said state sensor is preferably closed when the contacts 51 are open, as shown in FIG. 2, and open when the contacts 51 are closed.

For the sake of clarity in FIG. 2, the link between the source 1 and the busbar 7 or the link between the source 2 and the busbar 7 are shown in the form of a current line. In the case of a three-phase network, this line generally consists of four conductive lines corresponding to the three phases and to the neutral conductor. The set of contacts 41 then has four contacts. The set of contacts 51 likewise has four contacts. Other variants are possible: for a single-phase network the set of contacts will have two contacts, and for a three-phase network without neutral the set of contacts will have three contacts.

The state sensors 42 and 52 are preferably electromechanical components. They may also be electronic devices: sensors sensing the position of the contacts 41, 51 via optical or magnetic detection; and output the position information in ‘all or nothing’ form by means of an electromechanical relay, of static electronic contacts or of a digital communication bus.

The contact 36 is linked via the link 55 to the state sensor 52, which is itself linked via the link 44 to the control auxiliary 43 of the switch 4.

In the same way, the contact 37 is linked via the link 45 to the state sensor 42, which is itself linked via the link 54 to the control auxiliary 53 of the switch 5.

The closure of the contact 36 controls the supply of power to the control auxiliary 43, which is linked to the contact 41 of the switch 4, in order to actuate the closure of the contact 41 when the state sensor 52 is closed. The link between the source 1 and the busbar 7 is thus established by the contact 41, and the load 8 is supplied with power. When the contact 52 is open, in correspondence with a closed contact 51, the closure of the contact 36 has no effect on the contact 41. It is therefore not possible to simultaneously close the contacts 41 and 51, thereby constituting electrical interlocking of the switches 4 and 5.

In the same way, the closure of the contact 37 controls the supply of power to the control auxiliary 53 linked mechanically to the contact 51 of the switch 5 in order to actuate the closure of the contact 51 when the contact 41 is open. The link between the source 2 and the busbar 7 is thus established, and the load 8 is supplied with power.

As shown in FIG. 2, if the main source 1 is available, the drive circuit 32 sends an order to close the contact 36 and an order to open the contact 37. The auxiliary source changeover switch 38 forms the link between the source 1 and a common point of the contacts 36 and 37. The order to close the contact 36 will thus have the effect of supplying the control auxiliary 43 of the switch 4 with power and of activating the closure of the switch 4, while the order to open the contact 37 will have the effect of cutting the supply of power to the electromechanical device 53 of the switch 5 and of opening the switch 5. The load 8 connected to the busbar 7 will be supplied with power by the source 1. The source 2 will be isolated and not linked to the busbar 7.

In case of unavailability of the source 1, and if the second source 2 is available, the drive circuit 32 controls the contact 36 open and the contact 37 closed. The switch 4 will thus be opened and the switch 5 will be closed, and the load 8 connected to the busbar 7 will be supplied with power by the secondary source 2. The source 1 will be isolated and not linked to the busbar 7.

In case of unavailability of both sources, the power supply 39 does not have a power source, the monitoring/control device 3 does not operate, the contacts 36 and 37 are open and, as a result, the switches 4 and 5 are open and the load 8 is not supplied with power.

As a source changeover switch is a device used in emergency situations to provide a backup power supply to a critical load, its operation must be very reliable. In particular, the source 1 and the secondary source 2 must generally not be linked simultaneously to the busbar 7. The schematic representation in FIG. 2 thus illustrates one particular simple method of electrical interlocking, requiring limited data processing means in the drive circuit 32.

This type of source changeover switch has drawbacks, however:
the use of more than two power sources rapidly complicates the wiring diagram. Specifically, if n sources are available, it is necessary to place n−1 state sensors 42, 52 in series in order to allow a single contact 41, 51 to close only when all of the others are open. This complexity is manifested in extensive wiring,
as the power supply of the control units 43, 53 is taken directly from the link to the main source 1 and secondary source 2, any variation in voltage or disturbance will be passed on to the control auxiliary. In particular, as the second source 2 is often a generating set that may have a rotational speed that fluctuates depending on its load and on the quality of its regulation, the delivered voltage may be outside the specification of the control auxiliary. An auxiliary supplied in a voltage range outside its specification may be damaged or operate ineffectively, and finally
the electrical isolation between the two sources 1, 2 may be broken by an isolation fault at the level of the contacts in the auxiliary source changeover switch 38 or indeed by a fault in the synchronization of the closure of said contacts, which may result in a short circuit between the source 1 and the second source 2. To eliminate this risk, protecting means 11 and 21, such as circuit breakers or fuses, must be used. This increases the cost and the wiring of the source changeover switch.

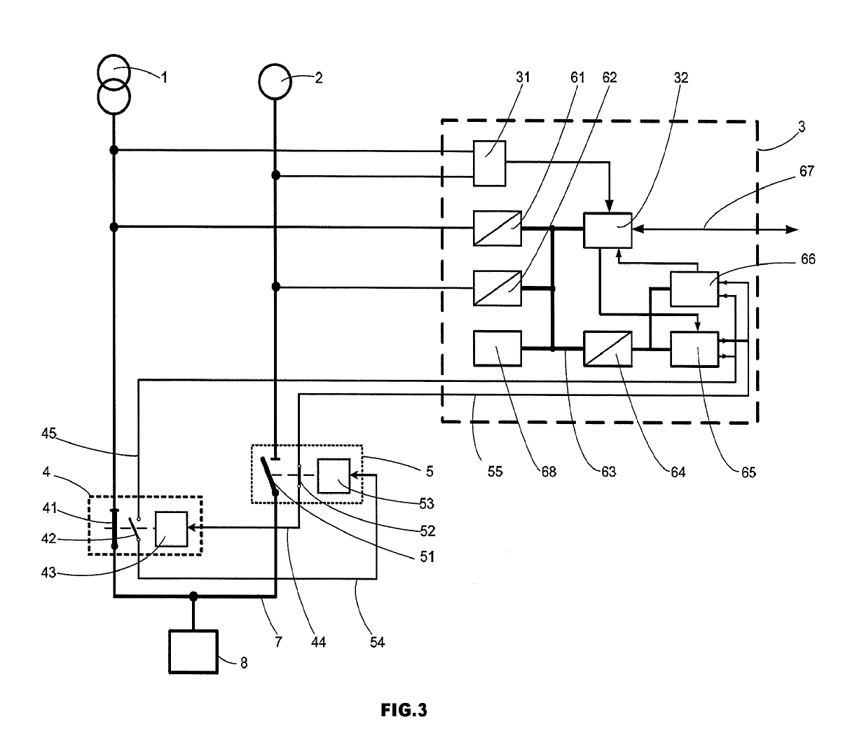

FIG. 3 is a schematic representation of a source changeover switch device used with a monitoring/control device 3 of the invention, in one preferred embodiment.

An AC/DC voltage converter 61 is connected between the source 1 and a supply bus 63. This converter converts a first voltage Us1 generated by the source 1, for example 400 volts 50 Hz, and applied to its input, to an intermediate voltage Ui delivered by its output to the supply bus 63, for example 24 volts, this value being given by way of non-limiting example. The AC/DC voltage converter 61 is an autonomous component that performs the voltage conversion as soon as the first voltage Us1 applied to its input exceeds a first minimum threshold Us1_mini, for example Us1_mini=50 volts.

A second AC/DC voltage converter 62 is connected between the secondary source 2 and the supply bus 63.

Identically to the converter 61, the second voltage converter 62 converts a second voltage Us2 generated by the secondary source 2 and applied to its input to an intermediate voltage, Ui, delivered by its output to the supply bus 63. It autonomously performs the voltage conversion as soon as the second voltage Us2 exceeds a second minimum threshold Us2_mini.

According to one preferred embodiment, the first voltage Us1 and the second voltage Us2 are AC voltages, and the intermediate voltage Ui is a DC voltage.

The values of the voltage thresholds Us1_mini and Us2_mini at the input of the voltage converters 61 and 62 are independent of one another. For practical reasons, as the AC/DC converters 61 and 62 are preferably identical, and as the amplitudes of the first and second voltages Us1 and Us2 are generally close, the threshold Us2_mini is preferably substantially equal to the threshold Us1_mini.

The voltage converters 61 and 62 are advantageously designed to operate over a large range of input voltages Us1 and Us2 in order to allow the source changeover switch device to be installed under highly varied conditions of use without requiring specific adaptation or a large number of industrial variants. The range of the voltage Us1 or Us2 that is acceptable to the AC/DC voltage converters 61 or 62 is from 60 volts to 600 volts, for example. The voltage converters 61 and 62 are moreover arranged in accordance with a known technique in order to operate without modification in an electrical installation whose sources 1 and 2 have a frequency of between a few hertz and several hundred hertz, for example from 16.33 Hz to 400 Hz.

Each voltage converter 61, 62 advantageously has internal galvanic isolation between its input and its output. This isolation is generally achieved via a transformer. There is no direct link between the input and the output of the converter, the transfer of power taking place via the exchange of magnetic flux in the transformer. The risk of an inadvertent electrical link between the sources 1 and 2 is thus extremely low.

The supply bus 63 preferably provides a supply of power to the drive circuit 32. Said drive circuit 32 is connected to monitoring/control circuits 65, 66 in order to control the switches 4 and 5 depending on the availability of the sources 1 or 2 and to monitor whether the controls have been performed correctly. Optionally, the drive circuit 32 may include a communication link 67 intended to communicate state information to or receive controls from an external device, for example a supervisor. This link 67 is particularly useful for diagnosing abnormal operation as it enables the feedback of information about the availability of the sources 1, 2 and the state sensors 42, 52.

The input of a DC/AC voltage converter 64 is connected to the supply bus 63. The voltage converter 64 converts the intermediate voltage Ui, present on its input, to a useful voltage Uc for supplying the monitoring/control circuits. The voltage converter 64 performs the voltage conversion as soon as the intermediate voltage Ui is present on its input.

The useful voltage Uc is independent of the voltages Us1, Us2 or Ui, and the value of the amplitude of the voltage Uc may therefore be chosen freely.

In practice, it is the nominal operating voltage chosen for the monitoring/control circuits that sets the amplitude of the useful voltage Uc that the voltage converter provides, and it is preferably one of the values commonly used in Europe or in the United States, or set in line with local standards. For example, a useful voltage Uc having an amplitude of 240 volts and a frequency of 50 Hz is suitable for many monitoring/control circuits in Europe and China, in particular for the control auxiliaries 43, 53 or the state sensors 42, 52. A useful voltage Uc having an amplitude of 400 volts and a frequency of 50 Hz is also very commonplace in industrial environments. For the United States market, a useful voltage having an amplitude of 120 volts and a frequency of 60 Hz will be perfectly suitable. The cost and the availability of the monitoring/control circuits is thus optimal, because these circuits will be very commonplace. Nonetheless, the use of the DC/AC voltage converter 64 makes it possible to take into consideration local specifications of the electrical installation. It is thus possible to provide another voltage amplitude and another frequency without having to change the voltage converter 64: the configuration of the converter, so as to define the amplitude and the frequency of the useful voltage Uc, may be performed for example in the factory, during the manufacture of the source changeover switch or during installation on site.

The use of the DC/AC converter 64 makes it possible to guarantee a voltage and a stable frequency for the useful voltage Uc, independently of fluctuations in the voltages Us1 or Us2 delivered by the sources 1 or 2. The monitoring/control circuits thus operate in the nominal voltage range for which they were designed. The risk of said circuits malfunctioning due to operation outside of specification is therefore eliminated. It is moreover possible to use monitoring/control circuits whose supply voltage ranges are small, and therefore circuits that are less expensive.

The monitoring/control circuits include:
a circuit 65 for controlling the activation of the switches and/or
a circuit 66 for monitoring the state of the switches and/or
a circuit 31 for determining the availability of the sources.

The circuit 65 controls the activation of the switches 4 and 5. It is connected upstream to the drive circuit 32 in order to receive orders to open or to close the switches 4 and 5, and downstream to the links 45 and 55.

A control to activate the switch 4 issued from the circuit 65 is routed via the link 55 to the state sensor 52. When the state sensor 52 is closed, the control is routed via the link 44 to the control auxiliary 43 of the switch 4. A control to activate the switch 5 will follow a similar path via the link 45, the state sensor 42, the link 54 and the control auxiliary 53.

In the same way as in FIG. 2, the switches 4 and 5 are interlocked.

The circuit 65 is connected downstream of the DC/AC converter 64 for its power supply. It receives a voltage Uc.

The circuit 66 is intended to monitor the state of the state sensors 42 and 52. It is connected upstream to the drive circuit 32 and connected downstream to the state sensors 42 and 52. In one preferred embodiment, the circuit 66 biases the state sensors 42 and 52 of the switches 1 and 2 in order to determine whether said contacts are open or closed, and transmits the state of the state sensors to the drive circuit 32.

The state-monitoring circuit 66 may include other inputs: for example, when the switches 4, 5 are disconnectable power circuit breakers, the circuit 66 may include inputs relating to the connected or disconnected state or to the armed or triggered state of the switches 4, 5.

The circuit 66 is connected downstream of the DC/AC converter 64 for its power supply. It receives a voltage Uc.

For the purpose of reducing manufacturing costs and/or streamlining functions, the circuits 65 and 66 may be arranged in a single module that is, connected downstream of the DC/AC converter 64 by a single link for its power supply.

The circuit 31 provides information on the availability of the sources 1, 2 to the drive circuit 32. It may receive its power supply from the supply bus 63 or be connected downstream of the DC/AC converter 64. In one preferred embodiment, the circuit 31 draws its power directly from the sources 1 and 2 to which it is linked, as shown in FIG. 3.

Optionally, a backup power supply device 68 is connected to the supply bus in order to deliver power to the supply bus 63 when the first and the second power source 1, 2 are unavailable. The power supply device 68 is preferably composed of an electric power storage means such as a battery or a set of capacitors, not shown in FIG. 3. It includes recharging circuits for recharging the storage means with power, at a storage voltage Ust, when at least one of the converters 61, 62 is operating. It also includes circuits making it possible to detect the absence of an intermediate voltage Ui on the supply bus, when the two converters 61 and 62 are not operating, and circuits for delivering, in this case, an intermediate voltage Ui to the supply bus by drawing the necessary power from the power storage means.

The intermediate voltage Ui is independent of the source voltages Us1, Us2 and of the useful voltage Uc. The intermediate voltage Ui may therefore be chosen freely. It is preferably set at a value allowing design to be made simple. In the case where a backup power supply device 68 is connected to the supply bus 63, it is beneficial to set the voltage Ui to a value substantially equal to the nominal storage voltage Ust of the power storage means of the backup device 68. For example, Ust=24 volts or 48 volts, which are voltages conventionally employed for storage means using one or more batteries mounted in series. In the absence of a backup power supply device 68, the intermediate voltage Ui may be set in order to be adapted to the power supply of the drive circuit 32, for example 5 or 12 volts. More generally, the higher the intermediate voltage Ui, the lower the current in the supply bus 63. The power lost through Joule heating will be lower.

The drive circuit 32 preferably includes a human-machine interface enabling an operator to perform any operation for monitoring or controlling the source changeover switch, for example in a maintenance phase. Advantageously, when no source is available and a backup power supply device 68 is present, an operator will be able to view the availability state of the first and second sources 1 and 2 given by the circuit 31 and the state of the switches 4 and 5 given by the state-monitoring circuit 66 in order to make a diagnosis.

As a variant, the AC/DC voltage converters 61, 62 may provide the information about the availability of the sources 1, 2 directly to the drive circuit 32 by means of a direct link, not shown in FIG. 3. The circuit 31 for determining the availability of the sources is thus no longer necessary, and the cost of the drive circuit 32 is reduced.

The architecture of the monitoring/control device 3 as shown in FIG. 3 has several advantages:
the monitoring/control device 3 can easily be adapted to a configuration having n sources by the addition of as many AC/DC voltage converters 61, 62 as there are additional sources 1, 2;
galvanic isolation is ensured between the control auxiliaries, the monitoring/control circuits and the sources;
the control auxiliaries are supplied with a useful voltage Uc that is independent of the first and second source voltages Us1 and Us2. The operating voltage of the control auxiliaries may therefore be standardized, thereby enabling a reduction in the number of variants of control auxiliaries, leading to a saving in the cost of the product;
the useful voltage Uc is independent of one of the source voltages Us1 or Us2 or of the component of said voltages Us1 or Us2, or indeed of the intermediate voltage Ui. This advantage is particularly beneficial in a three-phase power distribution regime, when the neutral is not distributed downstream of the sources 1 and 2. In contrast to the device described in the prior art illustrated in FIG. 2, it is possible to supply the monitoring/control circuits with power at a voltage equal to the simple voltage: to illustrate this advantage, when Us1 and Us2 are equal to 400 volts between phases, the useful voltage Uc may be set at 240 volts. This advantage makes it possible to use monitoring circuits having a supply voltage of 240 volts and that are less expensive and more commonplace than equivalent circuits operating at a voltage of 400 volts. It is impossible to achieve this configuration with the device from the prior art, since the connections for the supply of power to the control auxiliaries 43 and 53 originate directly from the sources, and there is therefore no way of connecting to a neutral link when the latter does not exist.

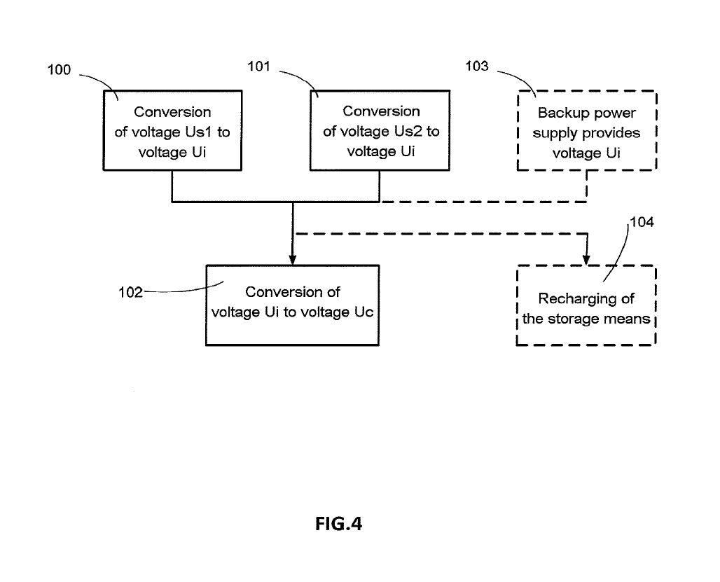

FIG. 4 is a flow chart of a method for supplying with power the device 3 intended to monitor/control a source changeover switch.

A step 100 consists in converting the first voltage Us1 of the first power source 1 to an intermediate voltage Ui for supplying the supply bus 63 by means of a first voltage converter 61.

In parallel, a step 101 consists in converting the second voltage Us2 of the second power source to an intermediate voltage Ui for supplying the supply bus 63 by means of a second voltage converter 62.

Following one or other of the preceding steps, a step 102 consists in converting the intermediate voltage Ui of the supply bus 63 to a useful voltage Uc.

When the first power source 1 and the second power source 2 are unavailable, and in the absence of a backup power supply device 68, step 102 is not executed, and the useful voltage Uc is therefore not provided.

When a backup power supply device 68 is present, two scenarios arise:
step 103 is executed when the intermediate voltage Ui is not delivered by converting either the first or second voltage Us1 or Us2: the backup power supply device 68 provides an intermediate voltage Ui that is available on the supply bus 63, and step 102 may be executed,
when the intermediate voltage Ui is delivered by converting either the first or second voltage Us1 or Us2, step 102 is executed and step 104 is executed in parallel: the backup power supply device 68 recharges its storage means by drawing power from the supply bus 63.

1. A device intended to monitor/control at least one first and one second switch that are arranged to connect at least one first and one second electric power source, respectively, to an electrical load depending on the availability of said sources, said device including a drive circuit and monitoring/control circuits,
comprising:
a supply bus,
a first voltage converter having an input linked to the first power source and an output connected to the supply bus, and arranged to convert a first voltage of the first power source to an intermediate voltage for supplying the supply bus,
a second voltage converter having an input linked to the second power source and an output connected to the supply bus and arranged to convert a second voltage of the second power source to an intermediate voltage for supplying the supply bus,
a third voltage converter arranged to convert the intermediate voltage of the supply bus to a useful voltage for supplying the monitoring/control circuits.

2. The device according to claim 1, wherein the monitoring/control circuits comprise:
a circuit for controlling the activation of the switches and/or
a circuit for monitoring the state of the switches and/or
a circuit for determining the availability of the sources.

3. The device according to claim 1, wherein the first and second converting means include galvanic isolation between the first electric power source and the supply bus and between the second electric power source and the supply bus, respectively.

4. The device according to claim 1, wherein the first voltage converter performs the conversion of the first voltage of the first power source to an intermediate voltage when the first voltage is higher than a first threshold and that the second voltage converter performs the conversion of the second voltage of the second power source to said intermediate voltage when the second voltage is higher than a second threshold.

5. The device according to claim 1, wherein the intermediate voltage is a DC voltage.

6. The device according to claim 1, wherein the useful voltage is substantially equal to the nominal operating voltage of the monitoring/control circuits.

7. The device according to claim 1, wherein a backup power supply device is connected to the supply bus to deliver the intermediate voltage to said supply bus when the first and the second power source are unavailable.

8. The device according to claim 7, wherein the backup power supply device includes a power storage means arranged to be charged to a storage voltage when the first and/or second power source are/is available.

9. The device according to claim 1, wherein the intermediate voltage is substantially equal to the storage voltage of the power storage means of the backup device.

10. The device according to claim 1, wherein the drive circuit is connected to the supply bus for its power supply.

11. A source changeover switch intended to connect a first or a second electric power source, respectively, to an electrical load depending on the availability of said sources, said source changeover switch comprising:
at least one first and one second switch,
at least two control auxiliaries, each auxiliary being intended to control one switch, respectively,
one or more state sensors, each state sensor interacting with one switch, respectively, to detect the state of said switch, and
a monitoring/control device according to claim 1.

12. The source changeover switch according to claim 11, wherein the input of the first converting means is connected between the first source and the first switch, and that the input of the second converting means is connected between the second source and the second switch.

13. A method for supplying with power a device intended to monitor/control a source changeover switch according to claim 11,
comprising the following steps:
converting the first voltage of the first power source to an intermediate voltage for supplying the supply bus with a first voltage converter,
converting the second voltage of the second power source to an intermediate voltage for supplying the supply bus with a second voltage converter,
converting the voltage of the supply bus to a useful voltage with a third voltage converter.

14. The method for supplying with power a device intended to monitor/control a source changeover switch according to claim 13, comprising the following steps if a backup power supply device is present:
providing, with the backup power supply device, the intermediate voltage to the supply bus when the two means for converting the first voltage or the second voltage are not operational, otherwise,
recharging the storage means of the backup power supply device when the intermediate voltage is provided by at least one of the means for converting the first voltage or the second voltage.
